(19) United States
(12) Patent Application Publication
(10) Pub. No.: US 2008/0080147 A1
(43) Pub. Date: Apr. 3, 2008

(54) Electronic control module

(75) Inventors: Ryan N. Steele, Dearborn, MI (US); David F. Haggitt, Orion, MI (US); Eric J. Zielinski, Livonia, MI (US)

Correspondence Address: FOLEY AND LARDNER LLP;SUITE 500, 3000 K STREET NW, WASHINGTON, DC, 20007, US

(73) Assignee: TK Holdings Inc.

(21) Appl. No.: 11/905,415

(22) Filed: Sep. 28, 2007

Related U.S. Application Data
(60) Provisional application No. 60/827,342, filed on Sep. 28, 2006.

(51) Int. Cl. H05K 1/14

(52) U.S. Cl. 361/736; 180/268; 180/271

(57) ABSTRACT

An electronic control module assembly includes a housing, a printed circuit board positioned inside the housing and a cover, mounted to the housing on top of the printed circuit board. The cover is configured to apply a spring-like force in multiple locations on the printed circuit board to rigidly fix the printed circuit board to the housing.

### CROSS REFERENCE TO RELATED APPLICATIONS

The present application claims priority to and the benefit of U.S. Provisional Patent Application No. 60/827,342, filed Sep. 28, 2006. The foregoing provisional application is incorporated by reference herein in its entirety.

### BACKGROUND

The present invention relates generally to the field of automotive electronic systems. Specifically, the present invention relates to the field of electronic control modules for vehicles.

An Electronic Control Module (ECM) is a subsystem consisting of CPUs and assorted signal inputs and outputs dedicated to controlling a component within a vehicle. ECM's range in complexity from an Engine Control Unit which handles the logic for managing the power-train system efficiency, to an Anti-lock Braking (ABS) Control unit that monitors vehicle speed and brake fluid, to a simple body module that controls automatic door locks or power windows. Modern vehicles may have anywhere in the range of seventy (70) or more electronic control modules.

ECM's typically contain sensitive electronic subcomponents that are mounted on a printed circuit board. In order to protect the ECM's components from the harsh conditions that can exist inside a vehicle, typical vehicle systems enclose ECM's in a module assembly. The module assembly is then mounted inside the vehicle. For example, ECM's can be mounted to the vehicle chassis. However, ECM's mounted in module assemblies inside a vehicle may be subject detrimental environmental conditions such as low frequency vibration. The low frequency vibration may negatively affect the performance of the ECM's sensors. In turn, the ECM may not perform optimally which results in overall poor vehicle performance. Accordingly, an apparatus and system is needed to reduce the negative effects on vehicle ECM's caused by external environmental conditions present in a vehicle.

### SUMMARY

According to one embodiment of the invention, an electronic control module assembly includes a housing, a printed circuit board positioned inside the housing and a cover, mounted to the housing on top of the printed circuit board. The cover is configured to apply a spring-like force in multiple locations on the printed circuit board to rigidly fix the printed circuit board to the housing.

According to yet another embodiment of the invention, an electronic control module assembly, further comprises a connector operably connected to the printed circuit board, wherein the connector facilitates a connection between the electronic control module and other systems.

According to another embodiment of the invention, one or more dimples are positioned on the inside of the cover, around the periphery of the cover. The dimples are configured to apply a spring-like force on the printed circuit board.

According to yet another embodiment of the invention, one or more edges of the cover are curved such that when the cover is mounted to the housing a spring-like force is applied on the printed circuit board.

According to one embodiment of the invention, the cover is configured so that the spring-like force applied to the PCB is uniformly distributed along the one or more curved edges of the cover.

According to another embodiment of the invention, the cover is configured so that the spring-like force applied to the PCB is concentrated near the center of the cover's one or more curved edges.

According to yet another embodiment of the invention, a restraint control module assembly for a vehicle includes a housing, a printed circuit board positioned inside the housing and a cover, mounted to the housing on top of the printed circuit board. The printed circuit board contains electronic components configured to diagnose vehicle acceleration and other vehicle conditions in order to control the deployment of vehicle safety systems. The cover is configured to apply spring-like force in multiple locations on the printed circuit board to rigidly fix the printed circuit board to the housing.

According to still another embodiment of the invention, an electronic stability control module assembly for a vehicle, includes a housing, a printed circuit board positioned inside the housing and a cover, mounted to the housing on top of the printed circuit board. The printed circuit board contains electronic components configured to measure vehicle motion. The vehicle motion includes but is not limited to lateral acceleration, longitudinal acceleration, vertical acceleration and vehicle orientation including yaw, pitch and roll. The cover is configured to apply spring-like force in multiple locations on the printed circuit board to rigidly fix the printed circuit board to the housing.

According to still another embodiment of the invention, a restraint and stability control module for a vehicle includes a housing, a printed circuit board positioned inside the housing and a cover, mounted to the housing on top of the printed circuit board. The cover is configured to apply spring-like force in multiple locations on the printed circuit board to rigidly fix the printed circuit board to the housing. The printed circuit board contains electronic components configured to diagnose vehicle acceleration and other vehicle conditions in order to control the deployment of vehicle safety systems and electronic components configured to measure vehicle motion.

According to one embodiment of the invention, a method for securely assembling an electronic control module includes the steps of providing a housing, positioning a printed circuit board inside the housing and mounting a cover to the housing on top of the printed circuit board, wherein the cover is configured to apply spring-like force in multiple locations on the printed circuit board to rigidly fix the printed circuit board to the housing.

It is to be understood that both the foregoing general description and the following detailed description are exemplary and explanatory only, and are not restrictive of the invention as claimed.

### BRIEF DESCRIPTION OF THE DRAWINGS

These and other features, aspects and advantages of the present invention will become apparent from the following description, appended claims, and the accompanying exemplary embodiments shown in the drawings, which are briefly described below.

FIG. 1 is perspective view of an ECM assembly according to one embodiment of the invention.

FIG. 2 is an exploded view of an ECM assembly according to another embodiment of the invention.

FIG. 3 is a perspective view of a ECM assembly cover according to yet another embodiment of the invention.

FIG. 4 is a side view of a ECM assembly cover according to still another embodiment of the invention.

### DETAILED DESCRIPTION

Embodiments of the present invention will be described below with reference to the accompanying drawings. It should be understood that the following description is intended to describe exemplary embodiments of the invention, and not to limit the invention.

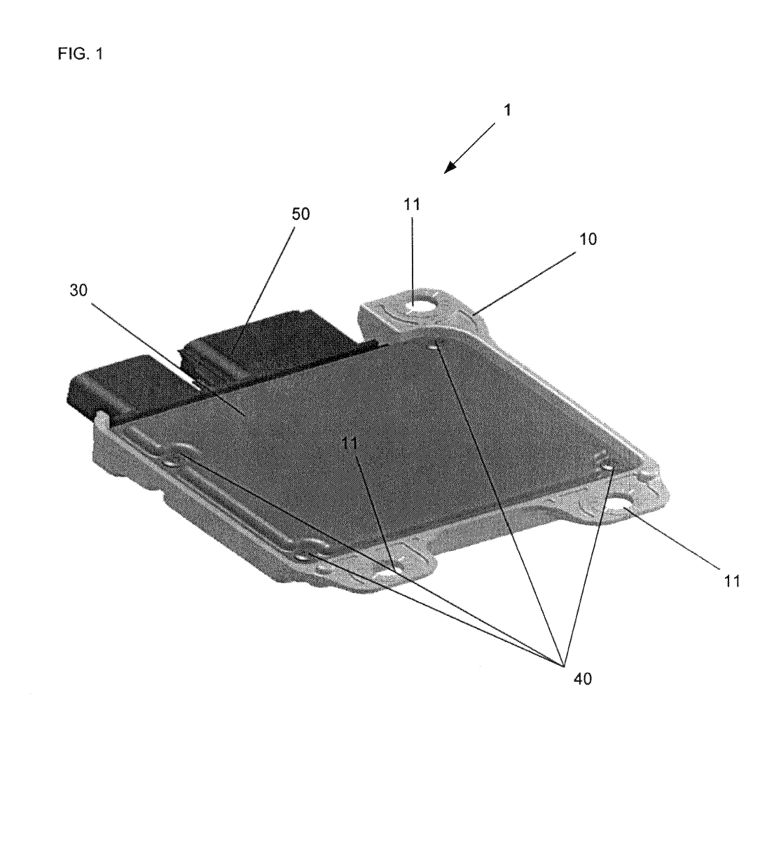

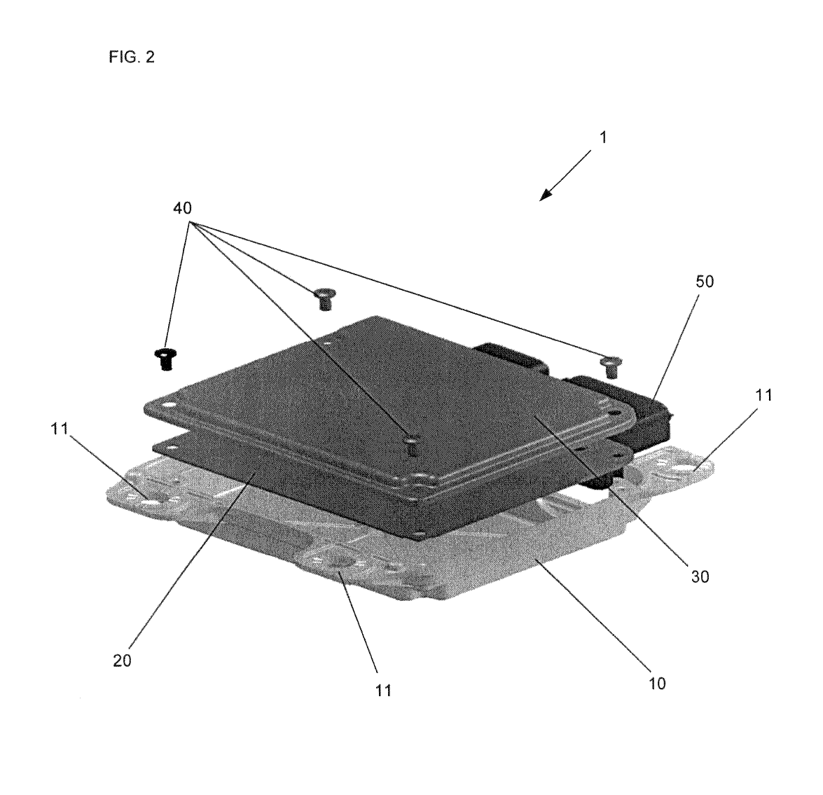

FIG. 1 shows an ECM assembly 1 according to one embodiment of the invention. FIG. 2 is an exploded view of the ECM assembly 1 shown in FIG. 1. The ECM assembly 1 consists of a housing 10, a printed circuit board (PCB) 20, a cover 30, one or more fasteners 40 and a connector 50.

The housing 10 includes an opening which is configured to receive the PCB 20 such that the PCB 20 fits securely within the housing 10. The housing 10 may include mounting portions 11 located at the periphery of the housing 10. The mounting portions 11 are used to securely mount the housing 10 to a portion of a vehicle. According to one embodiment of the invention, the mounting portions 11 are loops configured to receive a fastener such as a screw, nail, etc. The housing 10 may be comprised of any suitable material including, but not limited to, a cast metal such as aluminum or suitable plastics.

The PCB 20 may be any conventional printed circuit board suitable for ECM applications. The PCB 20 is positioned in the housing 10 opening. The PCB 20 may contain a plurality of circuit components, including but not limited to sensors configured for various control applications. The PCB 20 may be operably connected to the connector 50. The connector 50 facilitates communication between the PCB 20 and other systems.

As shown in FIGS. 1 and 2, a cover 30 is positioned over the PCB 20 to protect the PCB 20. The cover 30 may be made of any deflective material suitable for housing applications including plastics and metal alloys such as steel. In addition, the cover 30 has mounting portions for receiving fasteners 40. When mounted to the housing 10, the cover 30 is configured to apply spring-like forces in multiple locations on the PCB 20 in order to rigidly fix the PCB 20 to the housing 10. As shown in FIG. 2, the fasteners 40 are used to securely mount the cover 30 and PCB 20 to the housing 10. According to one embodiment of the invention, the fasteners 40 are threaded fasteners.

The shape of the cover 30 is configured to deform and apply spring-like forces on the PCB 20 in order secure the PCB 20 to the housing 10. The cover 30 applies spring-like forces on the PCB 20 in multiple locations of the PCB 20 in order to rigidly fix the PCB 20 into the housing 10. The PCB 20 is secured in such a way by the applied spring-like force of the cover 30 as to make the PCB 20 as stiff as possible. The stiffness of the PCB 20 reduces the effect of vibration on the performance of the ECM.

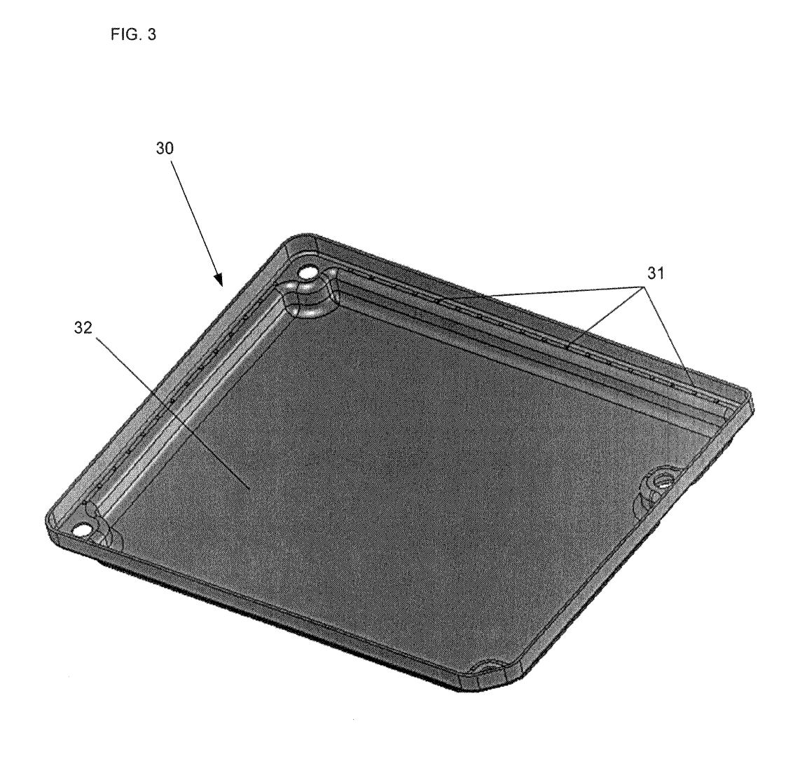

FIG. 3 is a cover 30 according to one embodiment of the invention. One or more dimples 31 are located on the inside surface 32 of the cover 30 around the periphery of the cover 30. When the cover 30 is mounted over a PCB 20, the dimples 31 act as springs, applying a spring-like force that presses the PCB 20 against the housing 10. In turn, the PCB 20 of the ECM assembly 1 is rigidly secured. The secured position of the PCB 20 reduces the negative effect that low vibration may have on the performance of the ECM assembly 1.

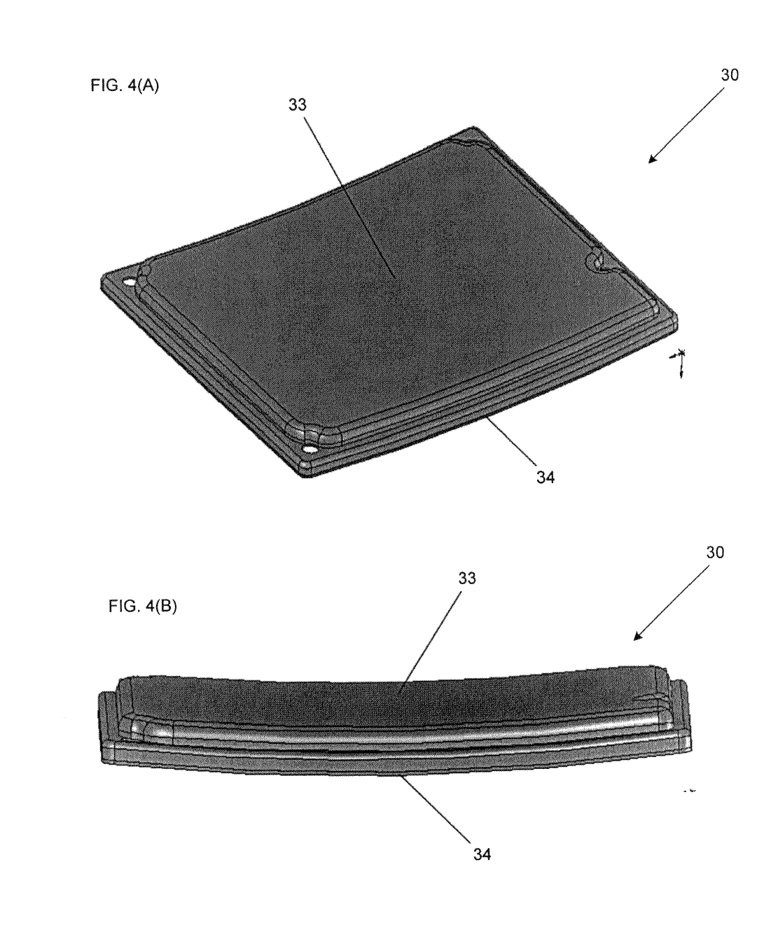

FIGS. 4(A) and 4(B) show a cover 30 according to another embodiment of the invention. The cover 30 is curved. FIGS. 4(A) and 4(B) show the cover 30 having a concave shape wherein the middle portion 33 of the cover is oriented lower relative to the end of the cover 30. According to another embodiment of the invention, the cover 30 is curved in one of the latitudinal or longitudinal directions or in both directions. The curve of the cover 30 is elastic in nature so that the cover 30 is not permanently deformed.

When the cover 30 is mounted on top of a PCB 20 to the housing 10 via fasteners 40, the cover 30 flattens, thus applying a spring-like force on the PCB 20 along the curved edge 34 of the cover 30. The applied spring-like force acts to secure the PCB 20 in place and substantially reduces the negative effects of vibrations on the components mounted on the PCB 20. According to one embodiment of the invention, the cover 30 can be designed such that the radius and depth of the curve provide a specific clamping force that can be either uniformly distributed along the length of the cover edge 34 or concentrated near the center of the cover edge 34 to yield optimum clamping results. The amount of force applied to the PCB 20 depends, in part, on the magnitude of the curve the cover 30 possesses. The larger the curve, the larger the force applied to the PCB 20.

The ECM assembly 1 as described above can be configured to perform various control functions in a vehicle. For example, the ECM assembly 1 may be a restraint control module (RCM). The RCM contains electronic sensors and circuits that diagnose vehicle acceleration and other vehicle conditions in order to control the deployment of vehicle safety systems such as airbags, seat belt pretensioners, etc. According to another embodiment of the invention, the ECM assembly 1 can be a electronic stability control module (or a Inertial Measurement Unit (IMU)) that is capable of measuring vehicle motion in six degrees of freedom. Specifically, the electronic stability control module is capable of measuring the acceleration of the vehicle in the lateral, longitudinal and vertical directions. In addition, the electronic stability control module is capable of measuring applied moment forces on the vehicle that affect vehicle orientation such as the yaw, pitch and roll of the vehicle. The electronic stability control module or IMU can be used by a vehicle control system to activate the vehicle's breaking systems or to alter the vehicle's course of direction. According to another embodiment of the invention, the RCM and electronic stability control system or IMU can be integrated into one module referred to here as a Restraints and Stability Control Module (RSCM).

The above-described invention has several advantages. The above-described ECM assembly 1 reduces the affect of vibration on the performance of the ECM. For example, the vehicle information obtained by the integrated RSCM module, described above, can vary depending on its mounting location inside the vehicle. The RSCM module must be coupled to the vehicle in such a way as to provide a certain amount of the acceleration and moments to transfer to the sensors. However, the RSCM requires signals that possess little or no noise. The ECM assembly 1 reduces the amount of low frequency vibration on the sensors that populate the PCB by securing the PCB in such a way as to make the PCB as stiff as possible. The stiffness of the PCB reduces vibration and improves performance of the RSCM.

The foregoing description of a preferred embodiment of the invention has been presented for purposes of illustration and description. It is not intended to be exhaustive or to limit the invention to the precise form disclosed, and modifications and variations are possible in light of the above teaching or may be acquired from practice of the invention. The embodiment was chosen and described in order to explain the principles of the invention and as a practical application to enable one skilled in the art to utilize the invention in various embodiments and with various modification are suited to the particular use contemplated. It is intended that the scope of the invention be defined by the claims appended hereto and their equivalents.

What is claimed is:

1. An electronic control module assembly, comprising:
a housing;
a printed circuit board positioned inside the housing; and
a cover, mounted to the housing on top of the printed circuit board,
wherein the cover is configured to apply spring force in multiple locations on the printed circuit board to rigidly fix the printed circuit board to the housing.

2. An electronic control module assembly, as claimed in claim 1, wherein fasteners are used to mount the cover to the housing.

3. An electronic control module assembly, as claimed in claim 1, further comprising a connector operably connected to the printed circuit board, wherein the connector facilitates a connection between the electronic control module and other systems.

4. An electronic control module assembly, as claimed in claim 1, wherein the housing includes mounting portions for mounting the electronic control module to a vehicle.

5. An electronic control module assembly, as claimed in claim 1, wherein a plurality of circuit components, including but not limited to sensors are mounted on the printed circuit board.

6. An electronic control module assembly, as claimed in claim 1, wherein one or more dimples are positioned on the inside cover of the cover, around the periphery of the cover, wherein the dimples are configured to apply a spring-like force on the printed circuit board.

7. An electronic control module assembly, as claimed in claim 1, wherein one or more edges of the cover are curved such that when the cover is mounted to the housing a spring-like force is applied on the printed circuit board.

8. An electronic control module assembly, as claimed in claim 7, wherein the cover is curved along the cover's latitudinal edges.

9. An electronic control module assembly, as claimed in claim 7, wherein the cover is curved along the cover's longitudinal edges.

10. An electronic control module assembly, as claimed in claim 7, wherein the cover is curved along both its latitudinal and longitudinal edges.

11. An electronic control module assembly, as claimed in claim 7, wherein the cover is configured so that the spring-like force applied to the PCB is uniformly distributed along the one or more curved edges of the cover.

12. An electronic control module assembly, as claimed in claim 7, wherein the cover is configured so that the spring-like force applied to the PCB is concentrated near the center of the one or more curved edges.

13. A restraint control module assembly for a vehicle, comprising:
a housing;
a printed circuit board positioned inside the housing; and
a cover, mounted to the housing on top of the printed circuit board,
wherein the cover is configured to apply spring force in multiple locations on the printed circuit board to rigidly fix the printed circuit board to the housing.

14. A restraint control module, as claimed in claim 13, wherein the printed circuit board contains electronic components configured to diagnose vehicle acceleration and other vehicle conditions in order to control the deployment of vehicle safety systems.

15. An electronic stability control module assembly for a vehicle, comprising:
a housing;
a printed circuit board positioned inside the housing; and
a cover, mounted to the housing on top of the printed circuit board,
wherein the cover is configured to apply spring force in multiple locations on the printed circuit board to rigidly fix the printed circuit board to the housing.

16. An electronic stability control module as claimed in claim 15, wherein the printed circuit board contains electronic components configured to measure vehicle motion.

17. An electronic stability control module as claimed in claim 16, wherein the vehicle motion includes but is not limited to lateral acceleration, longitudinal acceleration, vertical acceleration and vehicle orientation including yaw, pitch and roll.

18. A restraint and stability control module for a vehicle, comprising:
a housing;
a printed circuit board positioned inside the housing; and
a cover, mounted to the housing on top of the printed circuit board,
wherein the cover is configured to apply spring force in multiple locations on the printed circuit board to rigidly fix the printed circuit board to the housing.

19. A restraint and stability control module, as claimed in claim 18, wherein the printed circuit board contains electronic components configured to diagnose vehicle acceleration and other vehicle conditions in order to control the deployment of vehicle safety systems and electronic components configured to measure vehicle motion.

20. A method for securely assembling and electronic control module, comprising:
providing a housing;
positioning a printed circuit board inside the housing; and
and mounting a cover to the housing on top of the printed circuit board,
wherein the cover is configured to apply spring force in multiple locations on the printed circuit board to rigidly fix the printed circuit board to the housing.
